(19) United States
(12) Patent Application Publication
(10) Pub. No.: US 2021/0313773 A1
(43) Pub. Date: Oct. 7, 2021

(54) SEMICONDUCTOR LIGHT EMITTING DEVICE AND MANUFACTURING METHOD OF SEMICONDUCTOR LIGHT EMITTING DEVICE

(71) Applicant: Sony Semiconductor Solutions Corporation, Kanagawa (JP)

(72) Inventor: Yuusuke NAKAYAMA, Kanagawa (JP)

(21) Appl. No.: 17/051,608

(22) PCT Filed: Jun. 19, 2019
(86) PCT No.: PCT/JP2019/024231

§ 371 Date: Oct. 29, 2020

(30) Foreign Application Priority Data
Jul. 20, 2018 (JP) 2018-136626

(51) Int. Cl. H01S 5/30; H01S 5/343

(52) U.S. Cl. CPC H01S 5/3013; H01S 5/3054; H01S 5/34333

(57) ABSTRACT

A semiconductor light emitting device of one embodiment of the present disclosure incudes: a GaN substrate having, as a principal plane, a semipolar plane or a non-polar plane inclined from a c-plane in an m-axis direction or an a-axis direction within a range from 20° to 90° both inclusive; an active layer provided on the GaN substrate; and an n-type cladding layer provided between the GaN substrate and the active layer, and including a first layer on the active layer side and a second layer on the substrate side, the first layer including AlGaInN containing 0.5% or more of indium (In), and the second layer being lower in refractive index than the first layer.

### TECHNICAL FIELD

The present disclosure relates to a semiconductor light emitting device using, for example, gallium nitride (GaN) material and a manufacturing method thereof.

### BACKGROUND ART

Semiconductor lasers (LDs: Laser Diodes) and light emitting diodes (LEDs: Light Emitting Diodes) that use a nitride semiconductor and emit light in a range from a blue band to a green band for use as a light source have recently been vigorously developed. Among the above, a semipolar or non-polar nitride semiconductor, which is able to reduce an influence of a piezoelectric field, is effective in configuring a semiconductor light emitting device that emits light in a long wavelength band.

However, a gallium nitride (GaN) substrate having, as a principal plane for crystal growth, a semipolar or non-polar plane inclined from a c-plane in an m-axis or a-axis direction does not enable the use of a crystal surface suitable for the formation of a resonator end surface mirror by cleavage. Accordingly, for example, PTL 1 discloses a nitride semiconductor laser device in which a resonator end surface is formed by etching a nitride semiconductor layer.

### CITATION LIST

### Patent Literature

PTL 1: Japanese Unexamined Patent Application Publication No. 2009-164459

### SUMMARY OF THE INVENTION

Meanwhile, a semiconductor light emitting device using a nitride semiconductor has been desired to improve light extraction efficiency and light emission characteristics.

It is desirable to provide a semiconductor light emitting device that makes it possible to improve light extraction efficiency and light emission characteristics and a manufacturing method of the semiconductor light emitting device.

A semiconductor light emitting device of one embodiment of the present disclosure includes: a GaN substrate having, as a principal plane, a semipolar plane or a non-polar plane inclined from a c-plane in an m-axis direction or an a-axis direction within a range from 20° to 90° both inclusive; an active layer provided on the GaN substrate; and an n-type cladding layer provided between the GaN substrate and the active layer, and including a first layer on the active layer side and a second layer on the substrate side, the first layer including AlGaInN containing 0.5% or more of indium (In), and the second layer being lower in refractive index than the first layer.

A manufacturing method of a semiconductor light emitting device of one embodiment of the present disclosure includes: forming an n-type cladding layer including a first layer and a second layer in order of the second layer and the first layer on a GaN substrate having, as a principal plane, a semipolar plane or a non-polar plane inclined from a c-plane in an m-axis direction or an a-axis direction within a range from 20° to 90° both inclusive, the first layer including AlGaInN containing 0.5% or more of indium (In), and the second layer being lower in refractive index than the first layer; and forming an active layer on the n-type cladding layer.

In the semiconductor light emitting device of one embodiment and the manufacturing method of the semiconductor light emitting device of one embodiment of the present disclosure, the n-type cladding layer is provided between the GaN substrate and the active layer, the GaN substrate having, as the principal plane, the semipolar plane or the non-polar plane inclined from the c-plane in the m-axis direction or the a-axis direction within the range from 20° to 90° both inclusive, and the n-type cladding layer including the first layer on the active layer side and the second layer on the substrate side. The first layer includes AlGaInN containing 0.5% or more of indium (In) and the second layer has a lower refractive index than that of the first layer. This reduces, in forming a resonator end surface by etching, a rough surface of the resonator end surface to obtain a flat resonator end surface.

According to the semiconductor light emitting device of one embodiment and the manufacturing method of the semiconductor light emitting device of one embodiment of the present disclosure, the first layer and the second layer are provided as the n-type cladding layer respectively on the active layer side and on the GaN substrate side between the GaN substrate and the active layer, the GaN substrate having, as the principle plane, the semipolar plane or the non-polar plane inclined from the c-plane in the m-axis direction or the a-axis direction within the range from 20° to 90° both inclusive, the first layer including AlGaInN containing 0.5% or more of indium (In), and the second layer having a lower refractive index than that of the first layer, thus making it possible to obtain a flat resonator end surface. This makes it possible to improve light extraction efficiency and light emission characteristics.

It is to be noted that the effects described here are not necessarily limitative, and may be any of the effects described in the present disclosure.

### BRIEF DESCRIPTION OF DRAWINGS

FIG. 1 is a cross-sectional schematic diagram illustrating one example of a configuration of a semiconductor light emitting device according to an embodiment of the present disclosure.

FIG. 2 is a flowchart illustrating a formation method of the semiconductor light emitting device illustrated in FIG. 1.

FIG. 3A is an explanatory cross-sectional schematic diagram of the formation method of the semiconductor light emitting device illustrated in FIG. 1.

FIG. 3B is a cross-sectional schematic diagram subsequent to FIG. 3A.

FIG. 3C is a cross-sectional schematic diagram subsequent to FIG. 3B.

FIG. 4 illustrates a distribution of a refractive index in a layer-stacking direction and electric field intensity of the semiconductor light emitting device illustrated in FIG. 1.

FIG. 5 illustrates SEM images of end surfaces of a GaN layer (A) and an AlGaInN layer (B) formed by etching.

### MODES FOR CARRYING OUT THE INVENTION

In the following, some embodiments of the present disclosure are described in detail with reference to the drawings. The following description is directed to specific examples of the present disclosure, and the present disclosure is not limited to the following embodiments. In addition, the present disclosure is not limited to the arrangement, dimensions, dimensional ratios, and the like of respective components illustrated in the drawings. It is to be noted that description is given in the following order.

### 1. EMBODIMENT

(An example where an n-type cladding layer including a first layer containing 0.5% or more of In on an active layer side and a second layer lower in refractive index than the first layer is disposed and a resonator end surface is formed by etching)
1-1. Configuration of Semiconductor Light Emitting Device
1-2. Manufacturing Method of Semiconductor Light Emitting Device
1-3. Workings and Effects

### 1. EMBODIMENT

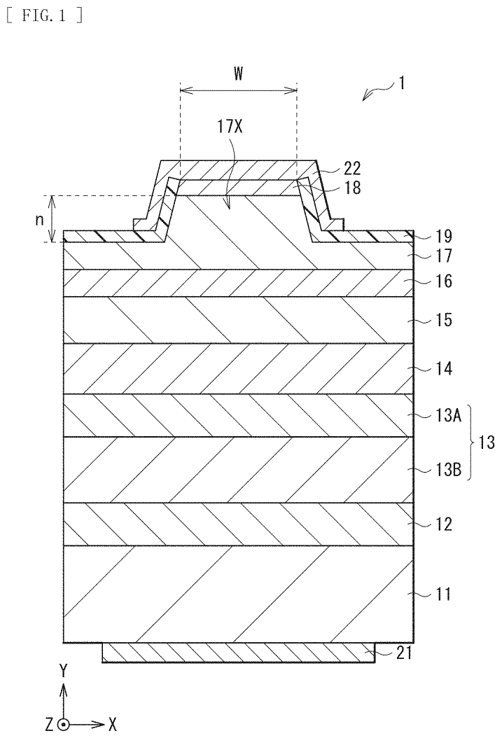

FIG. 1 schematically illustrates one example of a cross-sectional configuration of a semiconductor light emitting device (semiconductor laser 1) according to one embodiment of the present disclosure. The semiconductor laser 1 includes, for example, a nitride-based semiconductor laser that oscillates laser light in a visible region, particularly, with a wavelength of 450 nm or more, and is used as a light source for, for example, a laser display, a pointer, or the like. The semiconductor laser 1 of the present embodiment has a configuration in which an n-type cladding layer 13 is provided between a substrate 11 and an active layer 15. The cladding layer 13 includes two layers, that is, a first layer 13A that is disposed on the active layer 15 side and includes AlGaInN containing 0.5% or more of indium (In) and a second layer 13B that is disposed on the substrate 11 side and is lower in refractive index than first layer 13A. It is to be noted that FIG. 1 schematically illustrates the cross-sectional configuration of the semiconductor laser 1, where dimensions and shapes are different from actual dimensions and shapes.

### (1-1. Configuration of Semiconductor Light Emitting Device)

The semiconductor laser 1 includes a semiconductor layer on the substrate 11.

The semiconductor layer on the substrate 11 includes, for example, from the substrate 11 side, an underlayer 12, the n-type cladding layer 13, an n-type guide layer 14, the active layer 15, a p-type guide layer 16, a p-type cladding layer 17, and a contact layer 18, which are stacked in this order. The semiconductor laser 1 further includes a lower electrode 21 on a rear surface of the substrate 11 (a surface opposite to a surface where the above-described semiconductor layer is formed) and an upper electrode 22 on the contact layer 18.

The substrate 11 includes, for example, a GaN (gallium nitride) substrate having, as a principal plane, for example, a semipolar plane or a non-polar plane inclined from a c-plane in an m-axis direction or a-axis direction within a range from 20° to 90° both inclusive. A plane direction of the substrate 11 is, for example, any one of (1-100), (20-21), (20-2-1), (30-31), (30-3-1), (10-11), (11-20), (11-22), and (11-24). A thickness of the substrate 11 is, for example, in a range from 300 μm to 500 μm.

The semiconductor layer on the substrate 11 includes a nitride semiconductor. The nitride semiconductor includes, for example, GaN, AlGaN, GaInN, AlGaInN, or the like. The nitride semiconductor may contain, if desired, a boron (B) atom, a thallium (Tl) atom, silicon (Si), oxygen (O), an arsenic (As) atom, a phosphorus (P) atom, an antimony (Sb) atom, etc.

The underlayer 12 is provided on the substrate 11, and includes, for example, n-type GaN.

The n-type cladding layer 13 is provided on the underlayer 12, and includes, for example, the two layers, namely, the first layer 13A and the second layer 13B, as described above. The first layer 13A is disposed on the active layer 15 side and the second layer 13B is disposed on the substrate 11 side.

The first layer 13A includes, for example, Alₓ₁In_{y1}Ga_{z1}N (0≤x1≤0.995, 0005≤y1, 0<z1≤0.995, and x1+y1+z1=1). An In composition of AlGaInN included in the first layer 13A is preferably 0.5% or more as described above, more preferably 1% or more, further preferably 2% or more. For example, an upper limit thereof is preferably 20% or less, more preferably 15% or less, further preferably 10% or less. In this regard, it is preferable that a composition of aluminum (Al) be adjusted to cause a lattice constant of an AlGaInN layer included in the first layer 13A to be substantially equal to that of GaN. The first layer 13A is doped with, for example, silicon (Si), oxygen (O), or germanium (Ge) as an n-type dopant. For example, a thickness of the first layer 13A is preferably 50 nm or more, more preferably 100 nm or more, further preferably 200 nm or more. An upper limit of the thickness of the first layer 13A is, for example, 2000 nm or less. A surface roughness (for example, RMS or Ra) of a resonator end surface of the first layer 13A is smaller than that of the p-type cladding layer 17 to be described later.

The second layer 13B includes, for example, AlGaN. The second layer 13B has a refractive index lower than that of the first layer 13A. For example, the first layer 13A has a refractive index of 2.41, whereas the second layer 13B has, for example, a refractive index of 2.36. The second layer 13B is doped with, for example, silicon (Si) as an n-type dopant. For example, a thickness of the second layer 13B is preferably 200 nm or more, more preferably 500 nm or more, further preferably 800 nm or more.

The n-type cladding layer 13 may include another layer in addition to the first layer 13A and the second layer 13B and, in a case where, for example, three or more layers are stacked, the first layer 13A is preferably disposed at a position closest to the active layer 15 and, further, the first layer 13A preferably has the highest refractive index.

The n-type guide layer 14 is provided on the n-type cladding layer 13, and includes, for example, GaInN doped with silicon (Si). as an n-type dopant.

The active layer 15 is provided on the n-type guide layer 14. The active layer 15 has a single quantum well structure or a multiple quantum well structure where a plurality of quantum well layers is stacked with barrier layers interposed therebetween. Both the quantum well layers and the barrier layers of the active layer 15 include, for example, Alₓ₂In_{y2}Ga_{z2}N (0≤x2≤1, 0≤y2≤1, 0<z2≤1, and x2+y2+z2=1). The quantum well layers each preferably contain indium (In) and an In composition of the AlGaInN is, for example, preferably in a range from 15% to 50% both inclusive. A thickness of the active layer 15 is, for example, preferably in a range from 2 nm to 10 nm both inclusive. A peak wavelength of laser light oscillated from the active layer 15 is, for example, preferably 450 nm or more, more preferably 500 nm or more.

The p-type guide layer 16 is provided on the active layer 15, and includes, for example, undoped GaInN.

The p-type cladding layer 17 is provided on the p-type guide layer 16, and includes, for example, AlGaN doped with magnesium (Mg) as a p-type dopant. In a portion of the p-type cladding layer 17, a ridge portion 17X in the form of a thin stripe extending in a resonator direction for current confinement (in a Z-axis direction in FIG. 1) is formed as an optical waveguide. The ridge portion 17X has a width of, for example, 1 μm to 50 μm (an X-axis direction in FIG. 1: w) and a height of, for example, 0.1 to 1 μm (a Y-axis direction in FIG. 1: h). A length of the ridge portion 17X in the resonator direction is, for example, preferably in a range from 200 μm to 3000 μm both inclusive.

The contact layer 18 is provided on the ridge portion 17X of the p-type cladding layer 17, and includes, for example, GaN doped with magnesium (Mg).

A current confinement layer 19 including, for example, silicon oxide (SiO₂) is formed on the p-type cladding layer 17, which includes a side surface of the ridge portion 17X, and on a side surface of the contact layer 18.

The lower electrode 21 is formed on the rear surface of the substrate 11, and includes a metal. Examples of the lower electrode 21 include a multilayer film (Ti/Pt/Au) where, for example, titanium (Ti), platinum (Pt), and gold (Au) are stacked in order from the substrate 11 side. It is sufficient if the lower electrode 21 is electrically coupled to the n-type cladding layer 13 via the substrate 11, etc., and may not necessarily be formed on the rear surface of the substrate 11.

The upper electrode 22 is provided, for example, on the contact layer 18 and continuously on the side surface of the ridge portion 17X with the current confinement layer 19 interposed therebetween, and includes a metal as with the lower electrode 21. Examples of the upper electrode 22 include a multilayer film (Pd/Pt/Au) where, for example, palladium (Pd), platinum (Pt), and gold (Au) are stacked in order from the contact layer 18 side. The upper electrode 22 is extended in the form of a belt to cause a current to be confined, and a region corresponding to the upper electrode 22 in the active layer 15 serves as a light emitting region.

### (1-2. Manufacturing Method of Semiconductor Light Emitting Device)

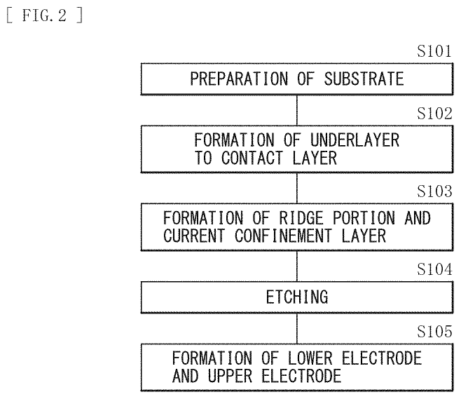

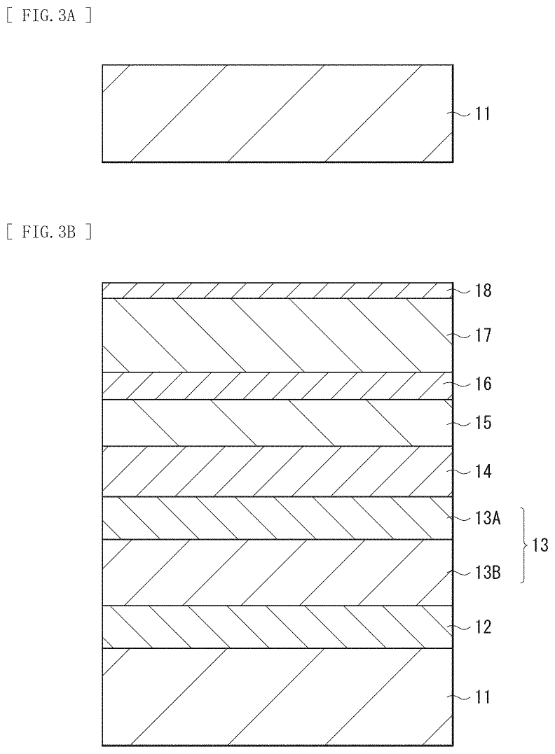

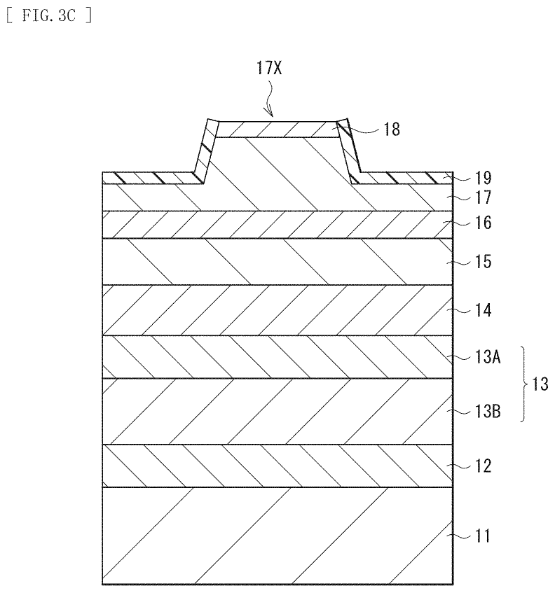

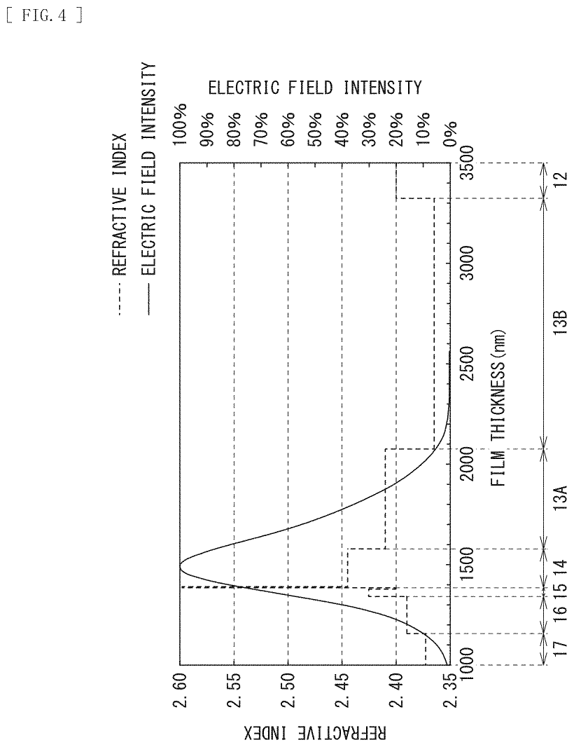

For example, the semiconductor laser 1 of the present embodiment may be manufactured as follows. FIG. 2 illustrates a flow of a manufacturing method of the semiconductor laser 1 and FIG. 3A to FIG. 3C illustrate the manufacturing method of the semiconductor laser 1 in the order of processes.

First, as illustrated in FIG. 3A, the substrate 11 including GaN having, for example, a (20-21) plane as a principal plane for growth is prepared in a reactor (step S101). Next, as illustrated in FIG. 3B, the underlayer 12, the second layer 13B and the first layer 13A included in the n-type cladding layer 13, the n-type guide layer 14, the active layer 15, the p-type guide layer 16, the p-type cladding layer 17, and the contact layer 18 are formed in this order on an upper surface (crystal growth surface) of the substrate 11 by, for example, MOCVD (Metal Organic Chemical Vapor Deposition; metal organic chemical vapor deposition) (step S102).

It is to be noted that in performing MOCVD, for example, trimethylgallium ((CH₃)₃Ga) is used as a source gas of gallium, for example, trimethylaluminum ((CH₃)₃Al) is used as a source gas of aluminum, and, for example, trimethylindium ((CH₃)₃In) is used as a source gas of indium. Further, ammonia (NH₃) is used as a source gas of nitrogen. Further, for example, monosilane (SiH₄) is used as a source gas of silicon and, for example, bis-cyclopentadienylmagnesium ((C₅H₅)₂Mg) is used as a source gas of magnesium.

Subsequently, the ridge portion 17X and the current confinement layer 19 are formed as illustrated in FIG. 3C (step S103). Specifically, the ridge portion 17X is formed, for example, by forming a mask on the contact layer 18 and selectively removing a portion of the contact layer 18 and a portion of the p-type cladding layer 17 by, for example, RIE (Reactive Ion Etching; Reactive Ion Etching). Next, for example, after an SiO₂ film is formed on the p-type cladding layer 17 and the contact layer 18, the current confinement layer 19 is formed to have an opening on an upper surface of the ridge portion 17X.

Subsequently, the resonator end surface is formed by etching (step S104). In this regard, it is preferable that dry etching be used as an etching method and the etching be applied to, preferably, at least a range from the contact layer 18 up to the n-type cladding layer 13, more preferably, up to the underlayer 12, further preferably, up to a depth sufficient to reach the substrate 11.

It is to be noted that RIE, RIBE (Reactive Ion Beam Etching; reactive ion beam etching), or the like is usable as the etching method. In any case, for example, a fluorine-based gas such as tetrafluoromethane (CF₄) or a chlorine-based gas such as chlorine (Cl₂) or silicon tetrachloride (SiCl₄) is selected as an etching gas in accordance with etching conditions. After the dry etching, a wet etching process with a solution such as potassium hydroxide (KOH) or tetramethylammonium hydroxide (TMAH) may be added to improve smoothness of a surface state.

Next, titanium (Ti), platinum (Pt), and gold (Au) are deposited as a film in order on the contact layer 18 and the current confinement layer 19 by, for example, vapor deposition, sputtering, or the like and then patterned into a desired shape by, for example, etching using photolithography, thereby forming the upper electrode 22. Finally, after a rear surface side of the substrate 11 is polished to achieve a predetermined thickness of the substrate 11, for example, a thickness of 90 μm, the lower electrode 21 is formed on the rear surface of the substrate 11. The semiconductor laser 1 of the present embodiment is thus completed.

In the semiconductor laser 1 of the present embodiment, a current is injected into the active layer 15 in response to application of a predetermined voltage to between the lower electrode 21 and the upper electrode 22, causing emission of light resulting from recombination of electrons and holes. The light is repeatedly reflected on a pair of resonator end surfaces and then outputted as laser light with a predetermined wavelength from one of the end surfaces. Laser oscillation is thus performed.

### (1-3. Workings and Effects)

As described above, semiconductor lasers and light emitting diodes that use a nitride semiconductor and emit light in a range from a blue band to a green band for use as a light source have recently been vigorously developed. Among the above, a semipolar or non-polar nitride semiconductor, which is able to reduce an influence of a piezoelectric field, is effective in configuring a semiconductor light emitting device that emits light in a long wavelength band.

However, a gallium nitride (GaN) substrate having, as a principal plane for crystal growth, a semipolar or non-polar plane inclined from a c-plane in an m-axis or a-axis direction does not enable the formation of a crystal surface suitable for a resonator end surface mirror by cleavage. Although, there is, for example, a method where a nitride semiconductor layer is etched to form a resonator end surface, the resonator end surface may be made rough to impair flatness thereof, thereby failing to provide a favorable resonator end surface mirror. The rough resonator end surface lowers light extraction efficiency at a light output surface and characteristics of a semiconductor laser.

In contrast, in the present embodiment, an n-type cladding layer including the first layer 13A on the active layer 15 side and the second layer 13B on the substrate 11 side is disposed between a top of the substrate 11, which has, as the principal plane, a semipolar plane or a non-polar plane inclined from the c-plane in the m-axis direction or the a-axis direction within the range from 20° to 90°, and the active layer 15, and a resonator end surface is formed using etching. The first layer 13A includes AlGaInN containing 0.5% or more of indium (In) and the second layer 13B has a refractive index lower than that of the first layer 13A.

FIG. 4 illustrates a distribution of a refractive index in a layer-stacking direction and electric field intensity of the semiconductor laser 1 of the present embodiment. It is found from FIG. 4 that a peak of the electric field intensity is closer to an n-type semiconductor layer than to the active layer 15.

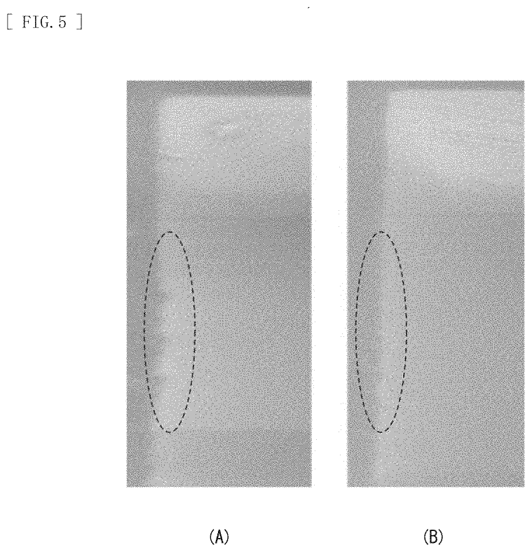

FIG. 5 illustrates SEM images of an end surface of a GaN layer (A) and an end surface of an AlGaInN layer (B) formed by etching. In a case where the GaN layer not containing indium (In) is etched, the end surface thereof is rough as seen from (A) of FIG. 5, whereas the etched surface of the AlGaInN layer containing In is improved in flatness as seen from (B) of FIG. 5. This is because of the presence or absence of In and, for example, in a case where a semiconductor layer containing In is etched by dry etching as with the AlGaInN layer, a product containing In, such as indium chloride (InCl₃), is produced. Indium chloride (InCl₃) has low volatility, and it is thereby speculated that the flatness of the etched surface is maintained.

In a typical semiconductor laser, an n-type cladding layer includes AlGaN or GaN. An end surface of AlGaN or GaN formed by etching has low flatness as illustrated in (A) of FIG. 4. In the semiconductor laser 1 of the present embodiment, the n-type cladding layer 13 has a two-layer structure as described above, where the first layer 13A including AlGaInN containing 0.5% or more of indium (In) is disposed on the active layer 15 side. The end surface formed by etching of the AlGaInN layer has high flatness as illustrated in (B) of FIG. 4. This makes it possible to improve the flatness of a laser light output surface.

As described above, in the semiconductor laser 1 of the present embodiment, the first layer 13A and the second layer 13B are disposed as the n-type cladding layer 13 respectively on the active layer 15 side and on the substrate 11 side between the substrate 11 and the active layer 15. The substrate 11 has, as the principle plane, a semipolar plane or a non-polar plane inclined from the c-plane in the m-axis direction or the a-axis direction within the range from 20° to 90°. The first layer 13A includes AlGaInN containing 0.5% or more of indium (In), and the second layer 13B is lower in refractive index than the first layer 13A. This reduces, in forming a resonator end surface, a rough surface in the vicinity of the active layer 15 closer to the n-type semiconductor layer where the peak of the electric field intensity exists, specifically, in the first layer 13A, improving the flatness of the resonator end surface. Therefore, it is possible to improve light extraction efficiency and light emission characteristics (laser characteristics).

Although the present disclosure has been described above with reference to the embodiment, the present disclosure is not limited to the above-described embodiment, and may be modified in a variety of ways. For example, the components, arrangement, numbers, etc. in the semiconductor laser 1 described as an example in the above-described embodiment are merely exemplary, and all the components may not necessarily be provided and any other component may be further provided.

Moreover, the effects described in the above-described embodiment, etc. are merely exemplary, and the effects of the present disclosure may be other effects or may further include other effects.

It is to be noted that the present disclosure may have the following configurations.

(1) A semiconductor light emitting device including:
a GaN substrate having, as a principal plane, a semipolar plane or a non-polar plane inclined from a c-plane in an m-axis direction or an a-axis direction within a range from 20° to 90° both inclusive;
an active layer provided on the GaN substrate; and
an n-type cladding layer provided between the GaN substrate and the active layer, and including a first layer on the active layer side and a second layer on the substrate side, the first layer including AlGaInN containing 0.5% or more of indium (In), and the second layer being lower in refractive index than the first layer.

(2) The semiconductor light emitting device according to (1), in which the first layer has a composition range of AlₓIn_{y}Ga_{z}N (0≤x≤0.995, 0005≤y≤1, 0<z≤0.995, and x+y+z=1).

(3) The semiconductor light emitting device according to (1) or (2), in which the first layer has a thickness in a range from 50 nm to 2000 nm both inclusive.

(4) The semiconductor light emitting device according to any one of (1) to (3), in which a plane direction of the GaN substrate is any one of (1-100), (20-21), (20-2-1), (30-31), (30-3-1), (10-11), (11-20), (11-22), and (11-24).

(5) The semiconductor light emitting device according to any one of (1) to (4), further including a p-type cladding layer on the active layer, in which
a surface roughness of the first layer included in a resonator end surface is smaller than a surface roughness of the p-type cladding layer.

(6) The semiconductor light emitting device according to any one of (1) to (5), in which the active layer oscillates laser light with a peak wavelength of 450 nm or more.

(7) The semiconductor light emitting device according to any one of (1) to (6), in which the first layer contains silicon (Si), oxygen (O), or germanium (Ge) as a dopant.

(8) A manufacturing method of a semiconductor light emitting device, the manufacturing method including:
forming an n-type cladding layer including a first layer and a second layer in order of the second layer and the first layer on a GaN substrate having, as a principal plane, a semipolar plane or a non-polar plane inclined from a c-plane in an m-axis direction or an a-axis direction within a range from 20° to 90° both inclusive, the first layer including AlGaInN containing 0.5% or more of indium (In), and the second layer being lower in refractive index than the first layer; and
forming an active layer on the n-type cladding layer.

(9) The manufacturing method of a semiconductor light emitting device according to (8), further including forming a p-type cladding layer on the active layer and thereafter forming a resonator end surface by dry etching.

This application claims the benefit of Japanese Priority Patent Application JP2018-136626 filed with the Japan Patent Office on Jul. 20, 2018, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A semiconductor light emitting device comprising:
a GaN substrate having, as a principal plane, a semipolar plane or a non-polar plane inclined from a c-plane in an m-axis direction or an a-axis direction within a range from 20° to 90° both inclusive;
an active layer provided on the GaN substrate; and
an n-type cladding layer provided between the GaN substrate and the active layer, and including a first layer on the active layer side and a second layer on the substrate side, the first layer including AlGaInN containing 0.5% or more of indium (In), and the second layer being lower in refractive index than the first layer.

2. The semiconductor light emitting device according to claim 1, wherein the first layer has a composition range of AlₓIn_{y}Ga_{z}N (0≤x≤0.995, 0005≤y≤1, 0<z≤0.995, and x+y+z=1).

3. The semiconductor light emitting device according to claim 1, wherein the first layer has a thickness in a range from 50 nm to 2000 nm both inclusive.

4. The semiconductor light emitting device according to claim 1, wherein a plane direction of the GaN substrate is any one of (1-100), (20-21), (20-2-1), (30-31), (30-3-1), (10-11), (11-20), (11-22), and (11-24).

5. The semiconductor light emitting device according to claim 1, further comprising a p-type cladding layer on the active layer, wherein
a surface roughness of the first layer included in a resonator end surface is smaller than a surface roughness of the p-type cladding layer.

6. The semiconductor light emitting device according to claim 1, wherein the active layer oscillates laser light with a peak wavelength of 450 nm or more.

7. The semiconductor light emitting device according to claim 1, wherein the first layer contains silicon (Si), oxygen (O), or germanium (Ge) as a dopant.

8. A manufacturing method of a semiconductor light emitting device, the manufacturing method comprising:
forming an n-type cladding layer including a first layer and a second layer in order of the second layer and the first layer on a GaN substrate having, as a principal plane, a semipolar plane or a non-polar plane inclined from a c-plane in an m-axis direction or an a-axis direction within a range from 20° to 90° both inclusive, the first layer including AlGaInN containing 0.5% or more of indium (In), and the second layer being lower in refractive index than the first layer; and
forming an active layer on the n-type cladding layer.

9. The manufacturing method of the semiconductor light emitting device according to claim 8, further comprising forming a p-type cladding layer on the active layer and thereafter forming a resonator end surface by dry etching.
